(19) United States
(12) Patent Application Publication
(10) Pub. No.: US 2024/0076522 A1
(43) Pub. Date: Mar. 7, 2024

(54) POLISHING LIQUID FOR POLISHING COMPOUND SEMICONDUCTOR SUBSTRATE

(71) Applicant: DISCO CORPORATION, Tokyo (JP)

(72) Inventors: Ayumu SAKAI, Tokyo (JP); Katsuyoshi KOJIMA, Tokyo (JP)

(21) Appl. No.: 18/461,214

(22) Filed: Sep. 5, 2023

(30) Foreign Application Priority Data
Sep. 7, 2022 (JP) 2022-141941

(51) Int. Cl. C09G 1/04

(52) U.S. Cl. CPC C09G 1/04

(57) ABSTRACT

A polishing liquid for polishing a compound semiconductor substrate includes an aqueous solution in which a permanganate and a water-soluble compound of a weak acid and a Group III element, a lanthanoid, or a Group IV element are dissolved. Preferably, the pH of the polishing liquid is 3 to 7. In addition, preferably, the concentration of the permanganate is not less than 2.50 wt %, and the concentration of the water-soluble compound is 0.55 wt % to 5.50 wt %.

### BACKGROUND OF THE INVENTION

### Field of the Invention

The present invention relates to a polishing liquid for polishing a compound semiconductor substrate.

### Description of the Related Art

In recent years, attention has been paid to a power device that has a high voltage resistance and is able to control a large current as compared to conventional devices formed by use of a silicon single crystal substrate. The power devices are formed, for example, on one surface side of a silicon carbide (SiC) single crystal substrate. It has been known that, prior to the formation of the devices on the one surface side of the SiC single crystal substrate, chemical mechanical polishing (CMP) is applied to the one surface side (see, for example, Japanese Patent Laid-open No. 2012-253259).

In the polishing method described in Japanese Patent Laid-open No. 2012-253259, in a state in which the SiC single crystal substrate is held under suction by a chuck table, the SiC single crystal substrate is polished while a polishing liquid is supplied between a fixed abrasive grain pad and the SiC single crystal substrate. It is particularly described in Japanese Patent Laid-open No. 2012-253259 that a highest polishing rate can be realized by use of potassium permanganate (KMnO₄) and ammonium cerium nitrate HNH₄)₂Ce(NO₃)₆) in the polishing liquid.

### SUMMARY OF THE INVENTION

However, the polishing liquid described in Japanese Patent Laid-open No. 2012-253259 is strongly acidic, and has a pH of, for example, 1 to 2. Hence, it is not easy to handle the polishing liquid, and the use of the polishing liquid is accompanied by a danger to a worker. The present invention has been made in consideration of such a problem, and it is an object of the invention to ensure easy handling as compared to a strongly acidic polishing liquid and to reduce danger to the worker.

In accordance with an aspect of the present invention, there is provided a polishing liquid for polishing a compound semiconductor substrate. The polishing liquid includes an aqueous solution in which a permanganate and a water-soluble compound of a weak acid and a Group III element, a lanthanoid, or a Group IV element are dissolved.

Preferably, the polishing liquid has a pH of 3 to 7.

Preferably, a concentration of the permanganate is not less than 2.50 wt %, and a concentration of the water-soluble compound is 0.55 wt % to 5.50 wt %.

The polishing liquid for polishing a compound semiconductor substrate according to the aspect of the present invention is weakly acidic owing to the component of the weak acid constituting the water-soluble compound, and, hence, easy handling thereof as compared to a strongly acidic polishing liquid can be ensured, and danger to a worker can be reduced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a partly sectional side view of a polishing apparatus;

FIG. 2 depicts results of an experiment in which the concentration of zirconyl acetate was varied stepwise, with the concentration of sodium permanganate fixed; and

FIG. 3 depicts results of an experiment in which the concentration of sodium permanganate was varied stepwise, with the concentration of zirconyl acetate fixed.

### DETAILED DESCRIPTION OF THE PREFERRED EMBODIMENT

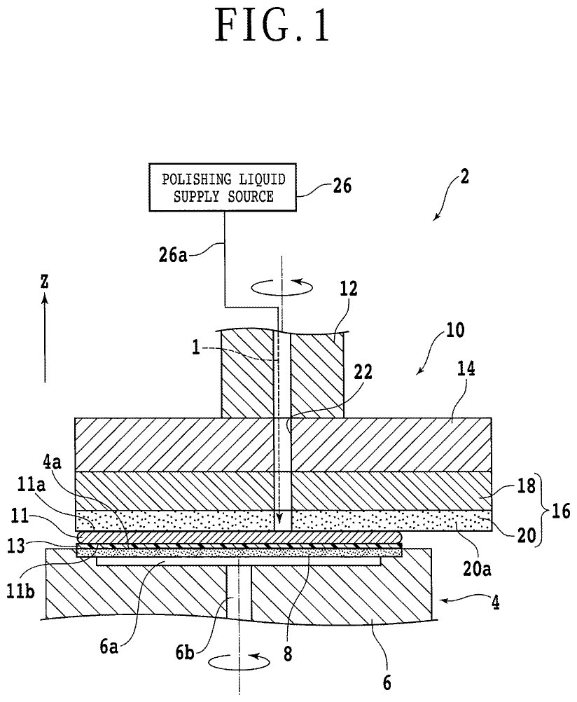

An embodiment according to an aspect of the present invention will be described with reference to the attached drawings. First, a polishing liquid 1 (see FIG. 1) of the present embodiment will be described. The polishing liquid 1 includes an aqueous solution in which a permanganate and a water-soluble compound are dissolved. As the permanganate, there is used sodium permanganate (NaMnO₄), potassium permanganate (KMnO₄), or the like. Note that, as the permanganate, use of sodium permanganate which is higher in solubility in water than potassium permanganate is preferred.

Other examples of the permanganate include permanganates configured by a metallic cation and a permanganate ion or ions such as silver permanganate (AgMnO₄), zinc permanganate (Zn(MnO₄)₂), magnesium permanganate (Mg(MnO₄)₂), calcium permanganate (Ca(MnO₄)₂), and barium permanganate (Ba(MnO₄)₂).

As the water-soluble compound, (i) a water-soluble compound of a weak acid and a Group III element, (ii) a water-soluble compound of a weak acid and a lanthanoid, or (iii) a water-soluble compound of a weak acid and a Group IV element is used.

Examples of the weak acid include acetic acid, citric acid, carbonic acid, phosphoric acid, oxalic acid, and boric acid, but the weak acid is not limited to these six kinds.

As (1) the Group III element, for example, yttrium (Y) may be mentioned, as (2) the lanthanoid, for example, lanthanum (La) and cerium (Ce) may be mentioned, and as (3) the Group IV element, or example, zirconium (Zr) may be mentioned.

In a case where acetic acid (CH₃COOH) is used as the weak acid, each of (1) yttrium acetate (Y(CH₃COO)₃), (2) lanthanum acetate (La(CH₃COO) 3) and cerium acetate (Ce(CH₃COO)₃), and (3) zirconyl acetate (also called zirconium oxyacetate) (ZrO(CH₃COO)₂) is used as the water-soluble compound.

In a case where citric acid (C₆H₈O₇) (expressed not in a rational formula but in a chemical formula for convenience' sake) is used as the weak acid, each of (1) yttrium citrate (Y(C₆H₅O₇)), (2) lanthanum citrate (La(C₆H₅O₇)) and cerium citrate (Ce(C₆H₅O₇)), and (3) zirconyl citrate ((ZrO)₃(C₆H₅O₇)2) is used as the water-soluble compound.

In a case where carbonic acid (H₂CO₃) is used as the weak acid, each of (1) yttrium carbonate (Y₂(CO₃)₃), (2) lanthanum carbonate (La₂(CO₃)₃) and cerium carbonate (Ce₂(CO₃)₃), and (3) zirconyl carbonate (ZrO(CO₃)) is used as the water-soluble compound.

In a case where phosphoric acid (H₃PO₄) is used as the weak acid, each of (1) yttrium phosphate (YPO₄), (2) lanthanum phosphate (LaPO₄) and cerium phosphate (CePO₄), and (3) zirconyl phosphate ((ZrO)₃(PO₄)₂) is used as the water-soluble compound.

In a case where oxalic acid (C₂O₄H₂) (expressed not in a rational formula but in a chemical formula for convenience' sake) is used as the weak acid, each of (1) yttrium oxalate (Y₂(C₂O₄)₃), (2) lanthanum oxalate (La₂(C₂O₄)₃) and cerium oxalate (Ce₂(C₂O₄)₃), and (3) zirconyl oxalate (ZrO(C₂O₄)) is used as the water-soluble compound.

In a case where boric acid (H₃BO₃) (expressed not in a rational formula but in a chemical formula for convenience' sake) is used as the weak acid, each of (1) yttrium borate (YBO₃), (2) lanthanum borate (LaBO₃) and cerium borate (CeBO₃), and (3) zirconyl borate ((ZrO)₃(BO₃)₂) is used as the water-soluble compound.

The polishing liquid 1 in which the permanganate and the water-soluble compound are dissolved is weakly acidic with a pH (hydrogen ion exponent) of 3 to 7 (3≤pH≤7), and is used when polishing a compound semiconductor substrate (workpiece) 11 as depicted in FIG. 1. In other words, the polishing liquid 1 is for polishing a compound semiconductor substrate.

The compound semiconductor substrate 11 is, for example, a single crystal substrate of silicon carbide (SiC), but may be a single crystal substrate of other compound semiconductors such as gallium nitride (GaN) and gallium arsenide (GaAs). Particularly, the polishing liquid 1 is weakly acidic, and is used when polishing a compound semiconductor substrate. On the other hand, a silicon single crystal substrate is in general polished under a basic condition, and, hence, the polishing liquid 1 is generally not used for the polishing of the silicon single crystal substrate.

Note that the polishing liquid 1 may further contain additives such as a pH adjustor, a viscosity adjustor, a rust preventive agent, or a preservative and free abrasive grains (for example, abrasive grains made of silica (SiO₂)) in addition to the above-described aqueous solution in which the permanganate and the water-soluble compound are dissolved. Since the polishing liquid 1 is weakly acidic owing to the component of the weak acid constituting the water-soluble compound, the use of the polishing liquid 1 enables easy handling as compared to a strongly acidic polishing liquid, and has a merit that danger to a worker can be reduced.

Next, the mechanism when the SiC single crystal substrate as the compound semiconductor substrate 11 is subjected to chemical mechanical polishing by use of the polishing liquid 1 including the aqueous solution in which sodium permanganate (NaMnO₄) and zirconyl acetate (ZrO(CH₃COO)₂) are dissolved will be described. Note that the mechanism described below is a present applicant's assumption, and the actual mechanism may differ therefrom.

First, when the polishing liquid 1 is supplied to one surface 11a (see FIG. 1) of the compound semiconductor substrate 11, Si atoms on the one surface 11a side are oxidized by an oxidizing action of permanganic acid (namely, an oxidant), to form a silicon oxide (SiO₂) layer. Note that C atoms in the SiC single crystal substrate are changed to carboxyl groups, carbon dioxide, or the like. The carboxyl groups are coordinated with zirconyl (ZrO²⁺) and abrasive grains, and are drawn out from the compound semiconductor substrate 11. In addition, carbon dioxide is dissolved in the polishing liquid 1 as carbonate ions, or becomes gas to be discharged from the polishing liquid 1 to the exterior.

The zirconyl (ZrO²⁺) and zirconium ions (Zr⁴⁺) derived from the zirconyl acetate in the polishing liquid 1 function as crosslinking agents, and adsorb the SiO₂ layer formed on the one surface 11a side and peel off the SiO₂ layer. In addition to this, the SiO₂ layer is scraped off physically by the abrasive grains. As a result, a new crystal surface of SiC is exposed. When the new crystal surface of SiC is exposed, similarly, (a) the formation of the SiO₂ layer by oxidation and (b) the adsorption and peeling-off of the SiO₂ layer by the zirconyl and the zirconium ions and physical scraping-off by the abrasive grains are alternately repeated.

Note that, for the polishing on the one surface 11a side to be made to proceed by use of the polishing liquid 1, the ability of the polishing liquid 1 to oxidize the one surface 11a of the compound semiconductor substrate 11 should be exhibited. In the present embodiment, the one surface 11a side is oxidized mainly by permanganic acid. The permanganic acid is stronger in oxidizing power when pH is low (namely, under an acidic condition) than when pH is high (namely, under a basic condition). In the present embodiment, the polishing liquid 1 is kept to be weakly acidic by the water-soluble compound of a weak acid and a transition metal element, and the oxidizing power of the permanganic acid can thereby be exhibited sufficiently as compared to the case under a basic condition.

Incidentally, it is considered that, in a case where an aqueous solution in which sodium permanganate and ammonium cerium nitrate are dissolved is used as in the conventional technology, permanganic acid oxidizes ammonium ions (NH₄⁺) and ammonia (NH₃) and the permanganic acid in the polishing liquid 1 is thereby consumed. Hence, it is considered that, since the amount of permanganic acid for oxidizing the one surface 11a side is decreased, the oxidizing power of the permanganic acid is relatively weakened. It is considered that, as it becomes difficult for oxidation on the one surface 11a side to proceed, the polishing rate is lowered.

On the other hand, the water-soluble compound of the present embodiment does not contain ammonium ions and ammonia, as mentioned above (namely, the concentrations of ammonium ions and ammonia are substantially 0 wt %). Hence, as compared to the conventional polishing liquid having potassium permanganate and ammonium cerium nitrate, the concentrations of ammonium ions and ammonia contained in the polishing liquid 1 are not more than the concentrations of the Group III element, the lanthanoid, and the Group IV element. For example, in the polishing liquid 1 of the present embodiment, the concentration of ammonium ions is not more than the lower limit of quantitative analysis by ion chromatography and is substantially 0 wt %.

It is to be noted, however, that, since ammonium ions present in a clean room in which polishing is conducted may be dissolved in the polishing liquid 1 in a trace amount, the ammonium ions in the polishing liquid 1 may not perfectly be 0 wt %. However, to the polishing liquid 1 of the present embodiment, basic substances and basic ions such as ammonia and ammonium ions are intentionally not added as a raw material at the time of manufacture. Hence, in the polishing liquid 1, the oxidizing power of permanganic acid can be exhibited sufficiently as compared to the conventional polishing liquid.

Next, a polishing method for the compound semiconductor substrate 11 by use of the polishing liquid 1 will be described. First, a polishing apparatus 2 to be used will be described. FIG. 1 is a partly sectional side view of the polishing apparatus 2. Note that a Z-axis direction depicted in FIG. 1 is substantially parallel to the vertical direction. The polishing apparatus 2 has a disk-shaped chuck table 4. To a lower surface side of the chuck table 4, a rotary shaft (not illustrated) whose longitudinal direction is disposed along the Z-axis direction is connected. The rotary shaft is provided with a driven pulley (not illustrated).

In the vicinity of the chuck table 4, a rotational drive source (not illustrated) such as a motor is provided. An output shaft of the rotational drive source is provided with a driving pulley (not illustrated). An endless belt (not illustrated) is wrapped around the driving pulley and the driven pulley, and motive power of the rotational drive source is transmitted to the rotary shaft of the chuck table 4. When the rotational drive source is operated, the chuck table 4 is rotated around the rotary shaft. The chuck table 4, the rotational drive source, and the like are supported by a moving plate (not illustrated) which is movable along a predetermined direction (for example, an X-axis direction orthogonal to the Z-axis direction).

The moving plate is movable along the X-axis direction together with the chuck table 4, the rotational drive source, and the like by a ball screw type moving mechanism (not illustrated). The chuck table 4 has a disk-shaped frame body 6 formed of a ceramic. A disk-shaped recess is formed in an upper part of the frame body 6. A disk-shaped porous plate 8 formed of a porous ceramic or the like is fixed in the recess. An upper surface of the porous plate 8 and an upper surface of the frame body 6 are flush with each other, to form a substantially flat holding surface 4a.

The porous plate 8 is connected to a suction source (not illustrated) such as a vacuum pump through flow channels 6a and 6b formed inside the frame body 6. When the suction source is operated, a negative pressure is transmitted to the upper surface of the porous plate 8. The compound semiconductor substrate 11 is mounted on the holding surface 4a. To another surface 11b of the compound semiconductor substrate 11 depicted in FIG. 1, a circular protective tape 13 formed of resin is stuck to prevent contamination, shock, and the like. The other surface 11b side of the compound semiconductor substrate 11 is held under suction by the holding surface 4a with the protective tape 13 therebetween such that the one surface 11a located on the side opposite to the other surface 11b is directed upward.

On the upper side of the holding surface 4a, a polishing unit 10 is disposed. The polishing unit 10 has a cylindrical spindle housing (not illustrated). The longitudinal direction of the spindle housing is disposed substantially in parallel to the Z-axis direction. To the spindle housing, a ball screw type Z-axis direction moving unit (not illustrated) for moving the polishing unit 10 along the Z-axis direction is connected. A part of a cylindrical spindle 12 is rotatably accommodated in the spindle housing. The longitudinal direction of the spindle 12 is disposed substantially in parallel to the Z-axis direction. A rotational drive source (not illustrated) such as a motor for rotating the spindle 12 is provided at a part on the upper side of the spindle 12.

To a lower end part of the spindle 12, a central part of an upper surface of a disk-shaped mount 14 is connected. The mount 14 has a diameter larger than a diameter of the holding surface 4a. To a lower surface of the mount 14, a disk-shaped polishing tool 16 substantially equal in diameter to the mount 14 is mounted. The polishing tool 16 has a disk-shaped base (also called a platen) 18 connected to the lower surface of the mount 14. The base 18 is formed of such metal as stainless steel. To a lower surface of the base 18, a polishing pad 20 substantially equal in diameter to the base 18 is fixed.

The polishing pad 20 has a main body section formed of a rigid foamed polyurethane resin. In the main body section, abrasive grains 20a made of silica are fixed. In other words, the polishing pad 20 is what is generally called a fixed abrasive gran pad. Incidentally, in the polishing pad 20, in place of the rigid foamed polyurethane resin, another rigid foamed resin or a non-woven fabric may be used. In addition, the abrasive grains 20a may not be fixed in the polishing pad 20. In this case, free abrasive grains are dispersed in the polishing liquid 1.

Radially central positions of the polishing pad 20, the base 18, the mount 14, and the spindle 12 are substantially coincident with each other, and a cylindrical through-hole 22 is formed in such a manner as to pass through these central positions. An upper end part of the through-hole 22 is connected to a polishing liquid supply source 26 through a conduit 26a. The polishing liquid supply source 26 includes a storage tank (not illustrated) for the polishing liquid 1, a pump (not illustrated) for feeding the polishing liquid 1 from the storage tank into the conduit 26a, and the like. The polishing liquid 1 supplied from the polishing liquid supply source 26 is supplied through the through-hole 22 to a central part of the polishing pad 20.

In polishing by use of the polishing apparatus 2, the chuck table 4 is rotated in a predetermined direction, and the spindle 12 is also rotated in a predetermined direction. The rotating speed is, for example, 500 rpm for the chuck table 4, and 495 rpm for the spindle 12 (namely, the polishing tool 16). By thus setting a speed difference in such a manner as to set the rotating speed of one of the chuck table 4 and the spindle 12 to an even number and set the rotating speed of the other to an odd number, it is possible to prevent the one surface 11a and the same region of the polishing pad 20 from keeping contact with each other for a predetermined time as in a case where the rotating speeds of the chuck table 4 and the spindle 12 are set equal.

In addition, in the present embodiment, a polished surface (the one surface 11a) is directed upward (namely, face-up), and the polishing liquid 1 is supplied to the polished surface from above the polished surface. Hence, the polishing liquid 1 can suitably be supplied to the polished surface even if the rotating speed of the chuck table 4 is set in excess of 120 rpm. On the other hand, in a case where the polished surface is directed downward (namely, face-down), the compound semiconductor substrate 11 is disposed at the position of the polishing pad 20, the polishing pad 20 is disposed at the position of the chuck table 4, and the polishing liquid 1 is supplied from above to a predetermined region of the polishing pad 20, the predetermined region being not in contact with the compound semiconductor substrate 11.

However, in a case where the polished surface is thus directed downward (namely, face-down), when the rotating speed of the polishing pad 20 is set in excess of 120 rpm, the polishing liquid 1 supplied to the polishing pad 20 is scattered toward outside in the radial direction of the polishing pad 20 by a centrifugal force, so that the polishing liquid 1 is not suitably supplied to the polished surface. As a result, it is difficult for the polishing rate to be increased even if the rotating speed of the polishing pad 20 is raised (in other words, the polishing does not conform to the law of Preston). In the present embodiment, since the face-up system is adopted, the polishing liquid 1 can suitably be supplied to the polished surface even when rotation at a high speed in excess of 120 rpm is conducted. In addition, the polishing rate can be increased as the rotating speeds of the chuck table 4 and the spindle 12 are raised. In other words, polishing in conformity with the law of Preston can be realized.

Note that, at the time of polishing, the chuck table 4 may be oscillated in a range of a predetermined distance along a predetermined direction (for example, the X-axis direction) by a moving mechanism. Specifically, an operation of moving the chuck table 4 by a predetermined distance in a +X direction and then moving the chuck table 4 by the predetermined distance in a −X direction is repeated. The predetermined distance is smaller than the radius of the compound semiconductor substrate 11, preferably smaller than 1/10 times the diameter of the compound semiconductor substrate 11. By thus oscillating the chuck table 4 at the time of polishing, there is obtained a merit that the ruggedness on the one surface 11a side can be reduced as compared to a case where the oscillation is not conducted.

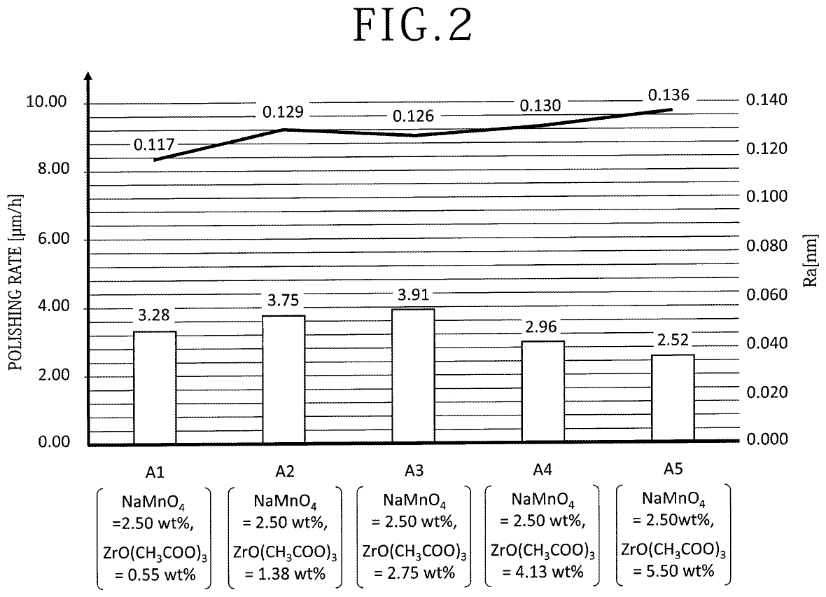

Next, results of an experiment in which a SiC single crystal substrate was polished by use of the polishing liquid 1 including an aqueous solution in which sodium permanganate (NaMnO₄) and zirconyl acetate (ZrO(CH₃COO)₂) were dissolved will be described with reference to FIG. 2. FIG. 2 depicts results of an experiment in which the concentration of sodium permanganate was fixed at 2.50 wt %, whereas the concentration of zirconyl acetate was varied stepwise from 0.55 wt % to 5.50 wt %, and the polishing rate (μm/h) and the ruggedness (Ra (nm)) of the polished surface were measured. As the abrasive grains 20a of the polishing pad 20, silica abrasive grains (grain diameter: 0.4 μm to 0.6 μm) were used. In addition, the polishing conditions were as follows.
Rotating speed of chuck table 4: 500 rpm
Rotating speed of polishing pad 20: 495 rpm
Flow rate of polishing liquid: 0.15 L/min
Pressure from polishing pad 20: 73.5 kPa
Polishing time: 6 minutes (namely, 360 seconds)
Compound semiconductor substrate 11: SiC single crystal substrate
Diameter of compound semiconductor substrate 11: 4 inches (approximately 100 mm)
Polished surface: Si surface

A1 in FIG. 2 represents a polishing liquid 1 containing 2.50 wt % of sodium permanganate and 0.55 wt % of zirconyl acetate. To prepare this polishing liquid 1, for example, 55 g of zirconyl acetate is added to a sufficient amount of pure water, 250 g of sodium permanganate is further added thereto, then the solution is diluted with pure water to 10 L, and thereafter the solution is stirred at 100 rpm by use of a stirrer for 30 minutes. Note that pH of A1 was 4.90 at 22.4° C. In a case where A1 was used, the polishing rate was 3.28 μm/h, and the ruggedness (Ra) of the one surface 11a after polishing was 0.117 nm. Note that Ra refers to arithmetic mean roughness. Ra is set according to JIS B 0601:2013, and refers to the mean of absolute values of height positions of an outline curve in a reference length.

A2 in FIG. 2 represents a polishing liquid 1 containing 2.50 wt % of sodium permanganate and 1.38 wt % of zirconyl acetate. For example, by use of 138 g of zirconyl acetate, A2 can be prepared by a process similar to that for A1. Note that pH of A2 was 4.65 at 22.2° C. In a case where A2 was used, the polishing rate was 3.75 μm/h, and Ra of the one surface 11a after polishing was 0.129 nm.

A3 in FIG. 2 represents a polishing liquid 1 containing 2.50 wt % of sodium permanganate and 2.75 wt % of zirconyl acetate. For example, by use of 275 g of zirconyl acetate, A3 can be prepared by a process similar to that for A1. Note that pH of A3 was 4.48 at 22.9° C. In a case where A3 was used, the polishing rate was 3.91 μm/h, and Ra of the one surface 11a after polishing was 0.126 nm.

A4 in FIG. 2 represents a polishing liquid 1 containing 2.50 wt % of sodium permanganate and 4.13 wt % of zirconyl acetate. For example, by use of 413 g of zirconyl acetate, A4 can be prepared by a process similar to that for A1. Note that pH of A4 was 4.44 at 22.5° C. In a case where A4 was used, the polishing rate was 2.96 μm/h, and Ra of the one surface 11a after polishing was 0.130 nm.

A5 in FIG. 2 represents a polishing liquid 1 containing 2.50 wt % of sodium permanganate and 5.50 wt % of zirconyl acetate. For example, by use of 550 g of zirconyl acetate, A5 can be prepared by a process similar to that for A1. Note that pH of A5 was 4.35 at 22.6° C. In a case where A5 was used, the polishing rate was 2.52 μm/h, and Ra of the one surface 11a after polishing was 0.136 nm.

Note that, in A4 and A5, the polishing rate was lowered although the concentration of zirconyl acerate was increased, as compared to A3. As the reasons for this, for example, the following two are presumed.

The first possible reason is that, since the viscosity of the polishing liquid 1 was raised and the frictional resistance between the polishing pad 20 and the one surface 11a was lowered, attendant on an increase in the concentration of zirconyl acetate, the polishing pad 20 slipped on the one surface 11a and polishing efficiency was lowered. The second possible reason is that, since the concentration of sodium permanganate was fixed at 2.50 wt %, the ability of oxidizing the one surface 11a side reached the ceiling. In other words, the ability of oxidizing the one surface 11a side (or the concentration of sodium permanganate) was constant in A1 to A5, so that, in A1 to A3, the polishing rate was raised with the concentration of zirconyl acetate. However, in A4 and A5, due to the lowering in polishing efficiency arising from the slipping of the polishing pad 20, the increase in polishing rate attendant on an increase in the concentration of zirconyl acetate was cancelled.

Taking the experimental results of FIG. 2 into account, the concentration of zirconyl acetate (the water-soluble compound) is preferably 0.55 to 2.75 wt %, and more preferably 1.38 to 2.75 wt %.

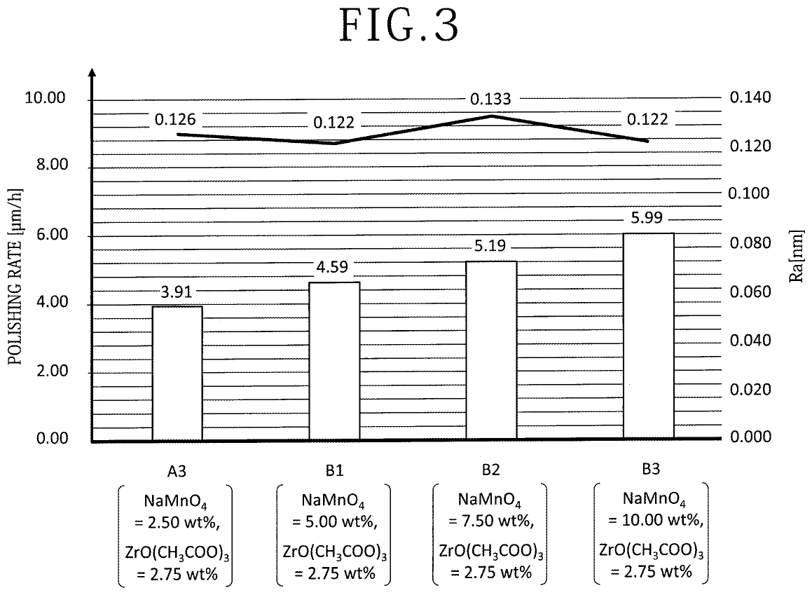

Next, results of an experiment in which the concentration of zirconyl acetate was fixed at 2.75 wt % will be described with reference to FIG. 3. FIG. 3 depicts results of an experiment in which the concentration of zirconyl acetate was fixed at 2.75 wt %, whereas the concentration of sodium permanganate was varied stepwise, and the polishing rate (μm/h) and the ruggedness (Ra (nm)) of the polished surface were measured. A3 depicted at the left end of a lower part of FIG. 3 is the same as A3 in FIG. 2.

B1 in FIG. 3 represents a polishing liquid 1 containing 5.00 wt % of sodium permanganate and 2.75 wt % of zirconyl acetate. By setting the weight of sodium permanganate used to be doubled as compared to A1, B1 can be prepared by a process similar to that for A1. Note that pH of B1 was 4.54 at 22.8° C. In a case where B1 was used, the polishing rate was 4.59 μm/h, and Ra of the one surface 11a after polishing was 0.122 nm.

B2 in FIG. 3 represents a polishing liquid 1 containing 7.50 wt % of sodium permanganate and 2.75 wt % of zirconyl acetate. By setting the weight of sodium permanganate used to be three times that for A1, B2 can be prepared by a process similar to that for A1. Note that pH of B2 was 4.61 at 22.8° C. In a case where B2 was used, the polishing rate was 5.19 μm/h, and Ra of the one surface 11a after polishing was 0.133 nm.

B3 in FIG. 3 represents a polishing liquid 1 containing 10.00 wt % of sodium permanganate and 2.75 wt % of zirconyl acetate. By setting the weight of sodium permanganate used to be four times that for A1, B3 can be prepared by a process similar to that for A1. Note that pH of B3 was 4.62 at 22.9° C. In a case where B3 was used, the polishing rate was 5.99 μm/h, and Ra of the one surface 11a after polishing was 0.122 nm. Note that, even if the concentration of sodium permanganate (the permanganate) is increased, the viscosity of the polishing liquid 1 is little influenced. Hence, the concentration of the permanganate in the polishing liquid 1 may be raised according to the desired polishing rate.

As is clear from the experimental results in FIG. 2 and FIG. 3, when the concentration of sodium permanganate (the permanganate) is set to be not less than 2.50 wt % and the concentration of zirconyl acetate (the water-soluble compound) is set to be 0.55 wt % to 5.50 wt %, polishing with Ra of the polished surface being less than 0.2 nm can be realized. Note that the present applicant has confirmed that, in polishing by use of A1 to A5 and B1 to B3, substantially no scratch was formed on the polished surface. By thus realizing substantially scratch-free polishing with Ra<0.2 nm, high specification demands in the post-steps after the polishing can be fulfilled.

Naturally, as mentioned above, since the polishing liquid 1 is weakly acidic owing to the component of the weak acid constituting the water-soluble compound, easy handling can be secured as compared to a strongly acidic polishing liquid, and there is obtained a merit that danger to the worker can be reduced. Other than the above, the structures, methods, and the like concerning the above-described embodiment can appropriately be modified in carrying out the present invention, insofar as the modifications do not depart from the scope of the object of the invention. For example, the water-soluble compound used for the polishing liquid 1 is not limited to zirconyl acetate.

Even in a case where yttrium acetate, lanthanum acetate, or cerium acetate is used, easy handling as compared to a strongly acidic polishing liquid can be ensured and danger to the worker can be reduced, by a mechanism similar to that in the case of zirconyl acetate. It can be rationally presumed that a similar effect can be obtained also in cases where yttrium citrate, lanthanum citrate, cerium citrate, zirconyl citrate, yttrium carbonate, lanthanum carbonate, cerium carbonate, zirconyl carbonate, yttrium phosphate, lanthanum phosphate, cerium phosphate, zirconyl phosphate, yttrium oxalate, lanthanum oxalate, cerium oxalate, zirconyl oxalate, yttrium borate, lanthanum borate, cerium borate, zirconyl borate, or the like is used as the water-soluble compound. Hence, transition metal elements of different Groups may be used in the polishing liquid 1. It is sufficient for the transition metal element used in the polishing liquid 1 to include at least one of a Group III element, a lanthanoid, or a Group IV element.

Incidentally, at the time of polishing, in place of supplying the polishing liquid 1 from the through-hole 22, the polishing liquid 1 may be sprayed up to a region on the lower surface side of the polishing pad 20, the region being not in contact with the compound semiconductor substrate 11, from a spray nozzle disposed on the radially outer side of the chuck table 4, to thereby supply the polishing liquid 1 from the polishing pad 20 to the compound semiconductor substrate 11.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A polishing liquid for polishing a compound semiconductor substrate, the polishing liquid comprising:
an aqueous solution in which a permanganate and a water-soluble compound of a weak acid and a Group III element, a lanthanoid, or a Group IV element are dissolved.

2. The polishing liquid according to claim 1, wherein the polishing liquid has a pH of 3 to 7.

3. The polishing liquid according to claim 1, wherein a concentration of the permanganate is not less than 2.50 wt %, and a concentration of the water-soluble compound is 0.55 wt % to 5.50 wt %.
